(19) United States
(12) Patent Application Publication
(10) Pub. No.: US 2004/0064619 A1
(43) Pub. Date: Apr. 1, 2004

(54) Memory card converting device

(76) Inventors: Wen-Tsung Liu, Shindian City (TW); Chia-Li Chen, Shindian City (TW); Mi-Chang Chen, Shindian City (TW)

Correspondence Address: Carry Computer Eng. Co., Ltd., P.O. Box No. 6-57, Chung-Ho, Taipei, 235, TW

(21) Appl. No.: 10/294,675

(22) Filed: Nov. 15, 2002

(30) Foreign Application Priority Data
Sep. 27, 2002 (TW) 091215370

(51) Int. Cl. H05K 7/10; G06F 13/00

(52) U.S. Cl. 710/301

(57) ABSTRACT

A memory card converting device mainly has a base with one lateral side thereof formed as an inserting end; from the inserting end to the inner portion of the base, a slot is disposed by overlapping the spaces for receiving memory cards of different standards, such as a smart media card, a multimedia card, a secure digital card and a memory stick card. Those memory cards utilize the sharing slot to convert and read the data signals between the memory card and said converting device. The main feature of the present invention is that a slot is defined in said slot for receiving an XD memory card thereby extending the application of said converting device to support memory cards of different standards.

### BACKGROUND OF THE INVENTION

1) Field of the Invention

The present invention relates to a memory card converting device, more particularly to a memory card converting device capable of even supporting an XD memory card via a single and sharing slot.

2) Description of the Prior Art

Storage media using semiconductor technique has been gradually developed due to the continuing progress of the information technique. The common names of the storage media include memory card, flash memory card or silicon disc card. Comparing with the traditional soft magnetic disc card and the compact disc card, the memory card is more convenient for carrying and for saving electricity; furthermore, the function of its data maintenance, speed of data transmission, rereading, rewriting, vibration and moisture prevention far surpasses said two kinds of traditional storage media. Therefore, it has become the new favored product of the storage media.

The specialty of the outstanding application of the memory card makes some of the international electronic factories, such as Sony, Toshiba, Siemens, Panasonic and SanDisk gradually manufactured memory cards of different dimensions, for examples, the PCMCIA ATA Flash card (PC), the compact flash card (CF), the smart media card (SM), the multimedia card (MMC), the memory stick card (MS) and the secure digital card (SD), to be applied to various information household appliances or digital electronic products. In addition, for reinforcing the information flow between the memory cards and all of the consuming type electronic products, such as computers and digital electronic products, a read device (referred as a card reader or a silicon disc drive) is produced for reading data on different types of memory cards. Even a read device for reading data on several kinds of memory card via a single slot position has been invented.

For the related products, many patents, for examples, Patent No. 182880 “Memory Card Signal Converting Device” of the Republic of China, Patent No. 3084232“Multiple-in-one Silicon Disc Drive” of Japan, Patent No. 513369 “Improved Multiple-in-one Silicon Disc Drive” of the People's Republic of China and Patent No. 286125“Multiple-in one Silicon Disc Drive I” of Korea have been granted.

However, said traditional memory card converting devices fail to suit the XD memory card of a new dimension launched by Olympus and FujiFirm in July, 2002. The XD memory card has even smaller size (20.0 mm×25.0 mm×1.7 mm) but higher capacity up to 8 GB. In other words, the XD memory card is not compatible with the different memory cards available in the market. Therefore, the problems of being unable to integrate, increasing the consumer's cost of purchasing extra card reader and not easy for management still trouble the users.

In viewing the abovementioned shortcomings, the inventor of said granted Patent and the present invention has researched, improved the conventional device and finally designed the present invention of a memory card converting device to solve said problems.

### SUMMARY OF THE INVENTION

The primary objective of the present invention is to provide a memory card converting device to solve the inconvenience and trouble of being unable to support the XD memory card. The converting device comprises a base; from an inserting end to the inner portion of the base, a slot position is disposed by overlapping the spaces for receiving different types of memory cards.

In addition to supporting a smart media (SM) card, a secure digital (SD) card, a multimedia card (MMC) and a memory stick (MS) card, another objective of the present invention is to support the XD memory card so as to extend the read application scope of a memory card. In other words, the present invention of a memory card converting device utilizes a single slot to support, store and access data from memory cards of five different kinds of standards.

To enable a further understanding of the detail structure and the effectiveness of the present invention, the brief description of the drawings below is followed by the detailed description of the preferred embodiment.

### BRIEF DESCRIPTION OF THE DRAWINGS

FIG. 1 is an exploded and schematic drawing of the present invention of a memory card converting device.

FIG. 2 is an assembled and schematic drawing of the present invention of a memory card converting device.

FIG. 3 is a schematic drawing of a smart memory card inserting into a base body of the present invention.

FIG. 4 is a schematic drawing of a memory stick card inserting into the base body of the present invention.

FIG. 5 is a schematic drawing of a multimedia/secure digital card inserting into the base body of the present invention.

FIG. 6 is a schematic drawing of an XD card inserting into the base body of the present invention.

### DETAILED DESCRIPTION OF THE PREFERRED EMBODIMENTS

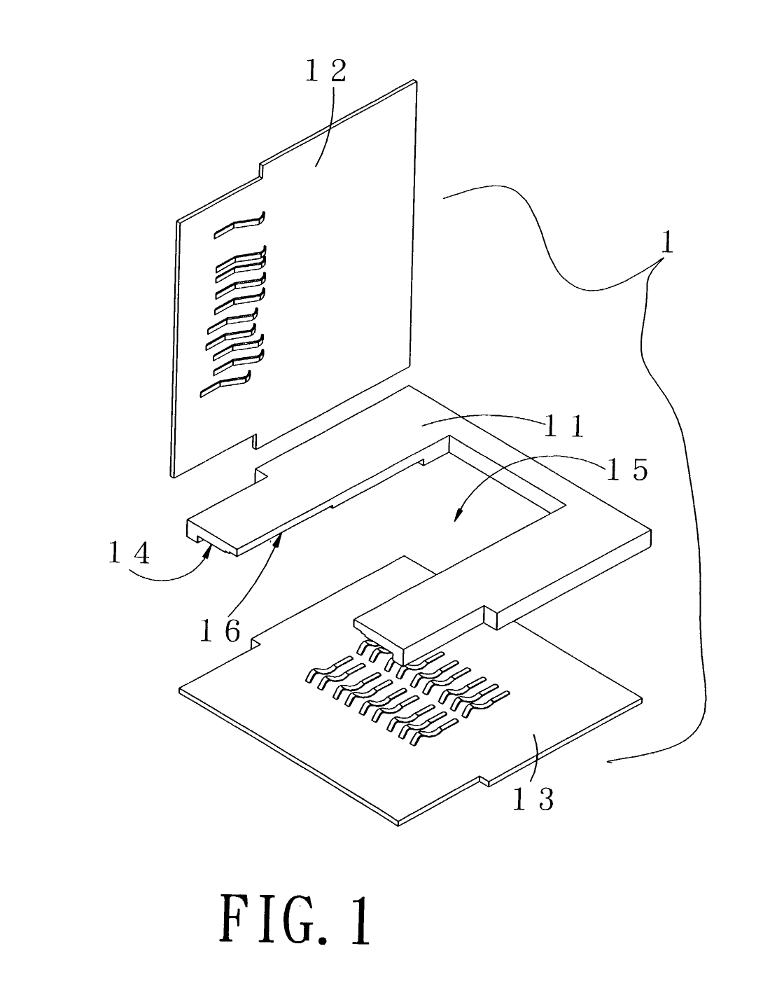

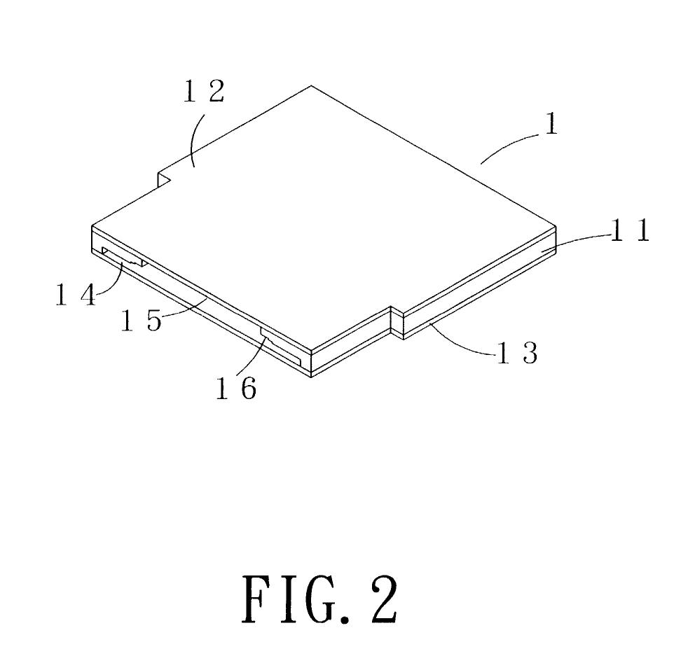

Referring to FIGS. 1 and 2, the present invention of a memory converting device comprises a base (1) assembled by a plate-shape base body (11), an upper base plate (12) and a lower base plate (13). Wherein the upper and lower base plates (12, 13) are assembled onto the plate-shape base body (11). The base (I) can be designed as a unitarily molded structure. A plurality of contacting elements (18) are disposed on the plate surface opposite to the plate-shape base body (11) for transmitting signals when different types of memory cards are inserted therein and the contacting elements (18) are connected.

More especially, a plurality of sets of contacting elements (18) disposed on the plate surfaces on the upper and lower base plates (12, 13) opposite the base (1) are capable of coupling with memory cards of different standards. In addition to a plurality of contacting elements (18) sets disposed on the upper and lower base plates (12, 13), the signals between the present invention and the memory cards are connected by other distributed and assembled circuits as well as a communication element disposed between two plates (12, 13). That is of a prior art element and will not be further described hereon.

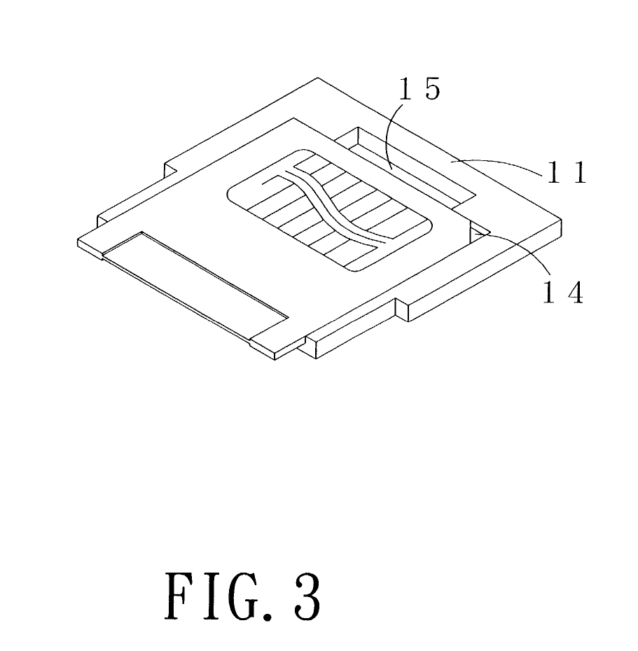

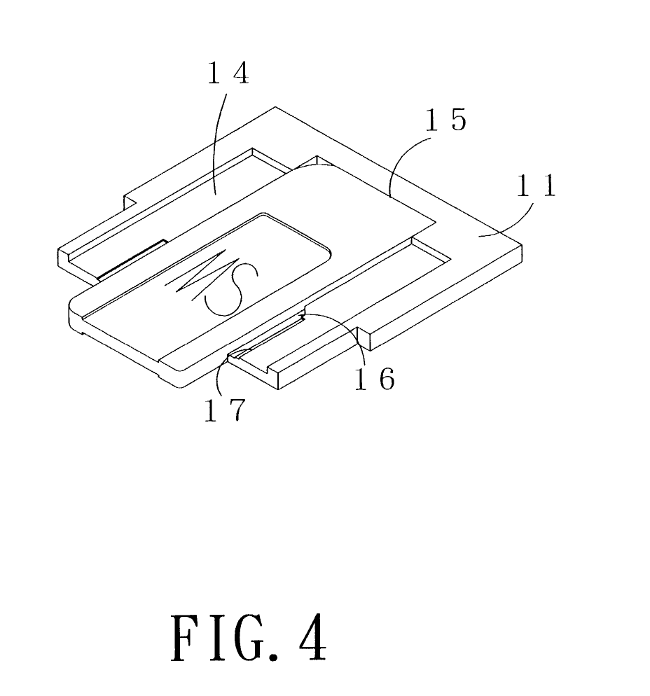

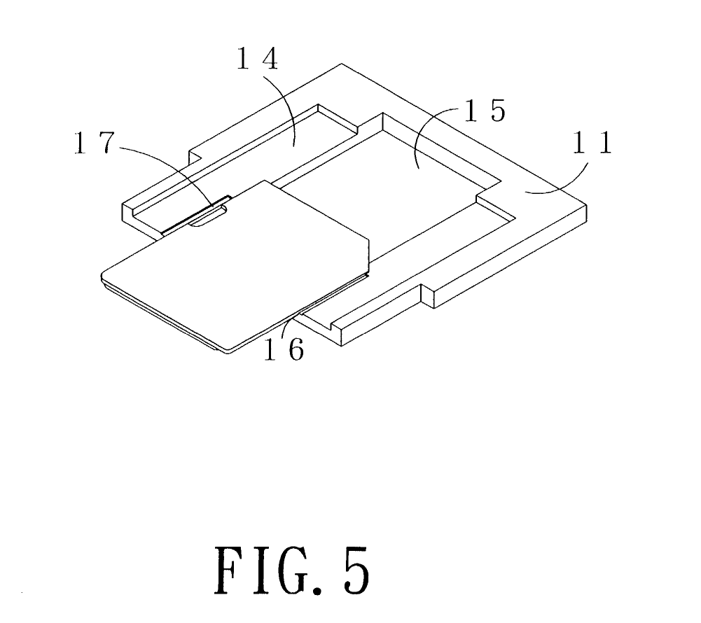

One lateral side of the plate-shape base body (11) is an open-type inserting end for inserting a memory card. From the inserting end to the inner portion thereof, a plurality of slots (14, 15, 16) are disposed by utilizing space change and overlapping the positions to save the most occupying space and to receive memory cards of different types and dimensions, such as a smart media (SM) card, a memory stick (MS) card, a secure digital (SD) card and a multimedia card (MMC), as indicated in FIGS. 3, 4 and 5.

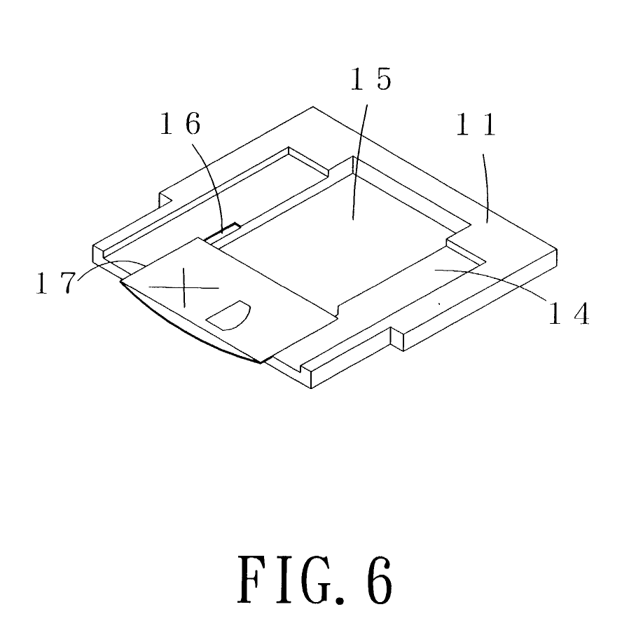

The features of the present invention are that a slot (17) is defined in the original space of the slots (14, 15, 16) for receiving an XD memory card, as indicated in FIG. 6. With the premise of not increasing extra space and but adapting the function of the XD memory card, the converting device extends the application of using memory cards of different types. Furthermore, the present invention of a memory card converting device is designed to be applied for the interfaces of a PCMCIA card or a compact flash (CF) card, various interfaces (for example, USB, lEEE1394, IDE) of a card reader, a compact disc drive, a burner, a copier, a portable products (for examples, a personal digital assistant, a digital camera, a digital camcorder, a digital walkman), a desktop computer or a notebook computer.

In summation, the present invention is capable of specifically achieving the expected and augmented effectiveness and design consideration. Its space configuration and application specialty are obviously superior to that of the conventional converting device.

It is of course to be understood that the embodiment described herein is merely illustrative of the principles of the invention and that a wide variety of modifications thereto may be effected by persons skilled in the art without departing from the spirit and scope of the invention as set forth in the following claims.

1. A memory card converting device comprising a base with a slot disposed from an inserting end to the inner portion thereof by overlapping the spaces for receiving memory cards of different types is characterized that a slot is defined in said slot for receiving an XD memory card.

2. The memory card converting device according to claim 1, wherein the base has a plate-shape base body, an upper base plate and a lower base plate; connection and assembly of circuits distributed on the upper and lower base plates as well as a communication element disposed between said two plates connect signals between the converting device and the memory cards.

3. The memory card converting device according to claim 2, wherein the communication element on the upper and lower base plates opposite the base plate surface includes a plurality of contacting element sets for coupling with memory cards of different standards.

4. The memory card converting device according to claim 1, wherein the slot receives a plurality of different types of memory cards including the XD card, a smart media (SM) card, a memory stick (MS) card, a secure digital (SD) card and a multimedia card (MMC).

5. A memory card converting device is comprised of a base assembled by a plate-shape base body, an upper plate and a lower plate; a plurality of contacting element sets as well as the connection and assembly of circuits distributed on the upper and lower base plates connect the signals; a slot disposed from an inserting end to the inner portion thereof by overlapping the spaces receives memory cards of different types; the present invention is characterized that a slot is defined in said slot for receiving an XD memory card.

6. The memory card converting device according to claim 1, wherein the received memory cards include XD, SM, MS, SD and MMC.
